(19) United States
(12) Patent Application Publication
(10) Pub. No.: US 2024/0030329 A1
(43) Pub. Date: Jan. 25, 2024

(54) SEMICONDUCTOR DEVICE AND METHOD FOR MANUFACTURING THE SAME

(71) Applicant: INNOSCIENCE (SUZHOU) TECHNOLOGY CO., LTD., Suzhou City (CN)

(72) Inventors: Pan WANG, Suzhou City (CN); Wen-Yuan HSIEH, Suzhou City (CN); Hung-Yu CHEN, Suzhou City (CN)

(21) Appl. No.: 17/440,794

(22) PCT Filed: Aug. 17, 2021
(86) PCT No.: PCT/CN2021/113061

§ 371 Date: Feb. 23, 2023

(51) Int. Cl. H01L 29/778; H01L 29/66; H01L 23/31; H01L 23/29; H01L 29/20

(52) U.S. Cl. CPC H01L 29/7786; H01L 29/66462; H01L 23/3171; H01L 23/3192; H01L 23/291; H01L 29/2003

(57) ABSTRACT

A semiconductor device includes a substrate, a first and a second nitride-based semiconductor layers, a doped nitride-based semiconductor layer, a gate electrode, a first and a second dielectric protection layers. The second nitride-based semiconductor layer has a bandgap greater than a bandgap of the first nitride-based semiconductor layer. The first and the second dielectric protection layers include oxygen. The first dielectric protection layer is conformal with a profile collectively constructed by the gate electrode, the doped nitride-based semiconductor layer, and the second nitride-based semiconductor layer. The second dielectric protection layer is in contact with the first dielectric protection layer. The first dielectric protection layer has an oxygen concentration less than that of the second dielectric protection layer.

### FIELD OF THE DISCLOSURE

The present disclosure generally relates to a nitride-based semiconductor device. More specifically, the present disclosure relates to a nitride-based semiconductor device having a multilayer structure which includes at least two dielectric protection layers with different oxygen concentrations and thicknesses, respectively, thereby improving the electrical characteristics thereof.

### BACKGROUND OF THE DISCLOSURE

In recent years, intense research on high-electron-mobility transistors (HEMTs) has been prevalent, particularly for high power switching and high frequency applications. III-nitride-based HEMTs utilize a heterojunction interface between two materials with different bandgaps to form a quantum well-like structure, which accommodates a two-dimensional electron gas (2DEG) region, satisfying demands of high power/frequency devices. In addition to HEMTs, examples of devices having heterostructures further include heterojunction bipolar transistors (HBT), heterojunction field effect transistor (HFET), and modulation-doped FETs (MODFET).

During the manufacturing process of III-nitride devices, the impurity gas or plasma may damage the gate electrode and the 2DEG region, thereby degrading the electrical properties thereof. Therefore, there is a need to improve device performance.

### SUMMARY OF THE DISCLOSURE

In accordance with one aspect of the present disclosure, a semiconductor device is provided. A semiconductor device includes a substrate, a first nitride-based semiconductor layer, a second nitride-based semiconductor layer, a doped nitride-based semiconductor layer, a gate electrode, a first dielectric protection layer and a second dielectric protection layer. The first nitride-based semiconductor layer is disposed above the substrate. The second nitride-based semiconductor layer is disposed on the first nitride-based semiconductor layer and has a bandgap greater than a bandgap of the first nitride-based semiconductor layer. The doped nitride-based semiconductor layer is disposed over the second nitride-based semiconductor layer. The gate electrode is disposed on the doped nitride-based semiconductor layer. The first dielectric protection layer includes oxygen and is disposed on the gate electrode and the second nitride-based semiconductor layer. The first dielectric protection layer is conformal with a profile collectively constructed by the gate electrode, the doped nitride-based semiconductor layer, and the second nitride-based semiconductor layer. The second dielectric protection layer includes oxygen and is disposed on and in contact with the first dielectric protection layer. The first dielectric protection layer has an oxygen concentration less than that of the second dielectric protection layer.

In accordance with one aspect of the present disclosure, a method for manufacturing a semiconductor device is provided. The method includes steps as follows. A first nitride-based semiconductor layer is formed. A second nitride-based semiconductor layer is formed on the first nitride-based semiconductor layer. A doped nitride-based semiconductor layer is formed over the second nitride-based semiconductor layer. A gate electrode is formed on the doped nitride-based semiconductor layer. A first dielectric protection layer including oxygen is formed on the gate electrode and the second nitride-based semiconductor layer. A second dielectric protection layer including oxygen is formed on and is in contact with the first dielectric protection layer. The first dielectric protection layer has an oxygen concentration less than that of the second dielectric protection layer and is thinner than the second dielectric protection layer.

In accordance with one aspect of the present disclosure, a semiconductor device is provided. A semiconductor device includes a substrate, a first nitride-based semiconductor layer, a second nitride-based semiconductor layer, a doped nitride-based semiconductor layer, a gate electrode and a multilayer structure. The first nitride-based semiconductor layer is disposed above the substrate. The second nitride-based semiconductor layer is disposed on the first nitride-based semiconductor layer and has a bandgap greater than a bandgap of the first nitride-based semiconductor layer. The doped nitride-based semiconductor layer is disposed over the second nitride-based semiconductor layer. The gate electrode is disposed on the doped nitride-based semiconductor layer. The multilayer structure is disposed on the gate electrode and the second nitride-based semiconductor layer. The multilayer structure includes a first dielectric protection layer and a second dielectric protection layer. The first dielectric protection layer includes oxygen and covers the gate electrode, the doped nitride-based semiconductor layer, and the second nitride-based semiconductor layer. The second dielectric protection layer includes oxygen and is disposed on and in contact with the first dielectric protection layer to form an interface therebetween. The multilayer structure has an oxygen concentration increasing and then decreasing from the second dielectric protection layer to the first dielectric protection layer through the interface.

By the above configuration, the first and a second dielectric protection layers of the multilayer structure have different thicknesses and oxygen concentrations, in which the first dielectric protection layer has the oxygen concentration less than that of the second dielectric protection layer. The multilayer structure can protect the underlying element layers from being damaged during the manufacturing process, including reducing the oxygen damage to the doped nitride-based semiconductor layer and the gate electrode. As such, the element layers in the semiconductor device can be well protected, thereby improving the electrical properties and reliability thereof.

### BRIEF DESCRIPTION OF THE DRAWINGS

Aspects of the present disclosure are readily understood from the following detailed description when read with the accompanying figures. It should be noted that various features may not be drawn to scale. That is, the dimensions of the various features may be arbitrarily increased or reduced for clarity of discussion. Embodiments of the present disclosure are described in more detail hereinafter with reference to the drawings, in which:

FIG. 1A is a vertical cross-sectional view of a semiconductor device according to some embodiments of the present disclosure;

FIG. 1B is an enlarged vertical cross-sectional view of a region in FIG. 1A according to some embodiments of the present disclosure;

FIG. 1C, FIG. 1D, FIG. 1E and FIG. 1F are different oxygen concentration distributions in the semiconductor device according to some embodiments of the present disclosure;

FIG. 2A, FIG. 2B, FIG. 2C, FIG. 2D, and FIG. 2E show different stages of a method for manufacturing a nitride-based semiconductor device according to some embodiments of the present disclosure; and

FIG. 3 is a vertical cross-sectional view of a nitride-based semiconductor device according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

Spatial descriptions, such as “on,” “above,” “below,” “up,” “left,” “right,” “down,” “top,” “bottom,” “vertical,” “horizontal,” “side,” “higher,” “lower,” “upper,” “over,” “under,” and so forth, are specified with respect to a certain component or group of components, or a certain plane of a component or group of components, for the orientation of the component(s) as shown in the associated figure. It should be understood that the spatial descriptions used herein are for purposes of illustration only, and that practical implementations of the structures described herein can be spatially arranged in any orientation or manner, provided that the merits of embodiments of this disclosure are not deviated from by such arrangement.

Further, it is noted that the actual shapes of the various structures depicted as approximately rectangular may, in actual device, be curved, have rounded edges, have somewhat uneven thicknesses, etc. due to device fabrication conditions. The straight lines and right angles are used solely for convenience of representation of layers and features.

In the following description, semiconductor devices/dies/packages, methods for manufacturing the same, and the likes are set forth as preferred examples. It will be apparent to those skilled in the art that modifications, including additions and/or substitutions may be made without departing from the scope and spirit of the present disclosure. Specific details may be omitted so as not to obscure the present disclosure; however, the disclosure is written to enable one skilled in the art to practice the teachings herein without undue experimentation.

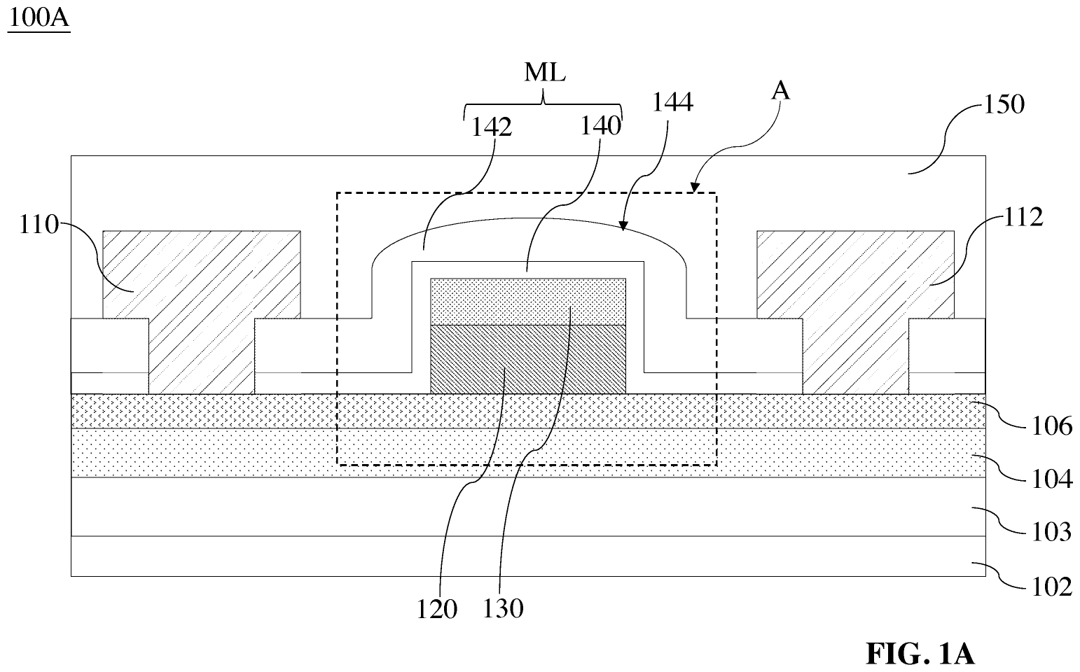

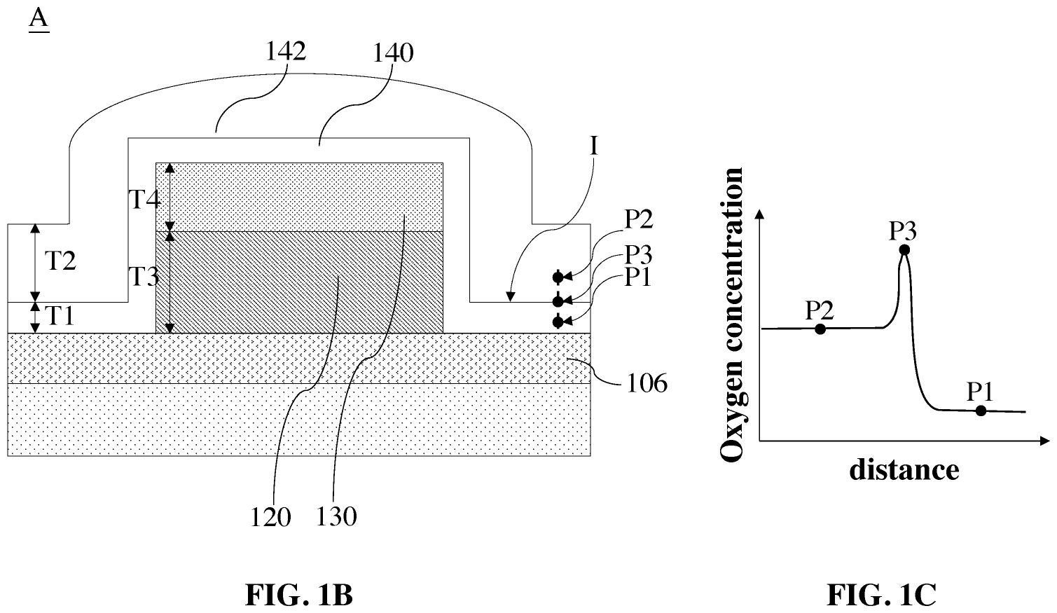

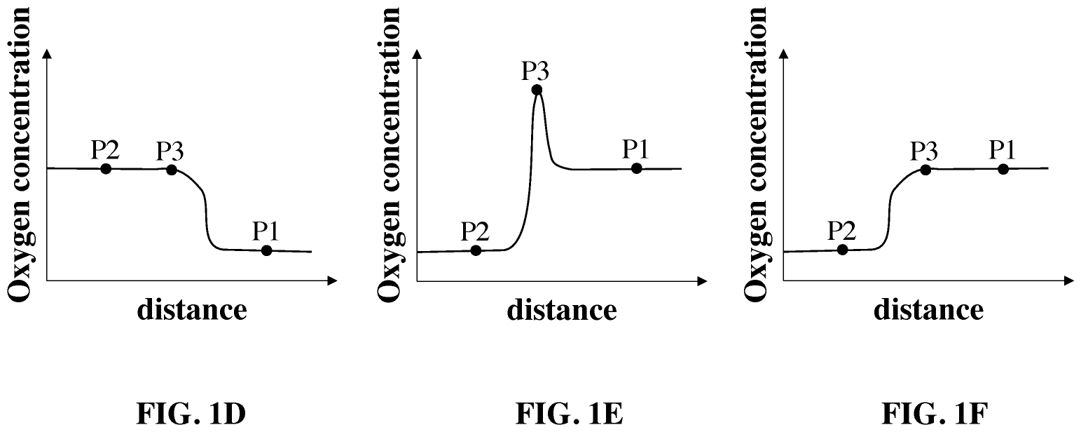

FIG. 1A is a vertical cross-sectional view of a semiconductor device 100A according to some embodiments of the present disclosure. The semiconductor device 100A includes a substrate 102, a buffer layer 103, nitride-based semiconductor layers 104 and 106, source/drain (S/D) electrodes 110 and 112, a doped nitride-based semiconductor layer 120, a gate electrode 130, dielectric protection layers 140 and 142, and a passivation layer 150.

The substrate 102 may be a semiconductor substrate. The exemplary materials of the substrate 102 can include, for example but are not limited to, Si, SiGe, SiC, gallium arsenide, p-doped Si, n-doped Si, sapphire, semiconductor on insulator, such as silicon on insulator (SOI), or other suitable substrate materials. In some embodiments, the substrate 102 can include, for example, but is not limited to, group III elements, group IV elements, group V elements, or combinations thereof (e.g., III-V compounds). In other embodiments, the substrate 102 can include, for example but is not limited to, one or more other features, such as a doped region, a buried layer, an epitaxial (epi) layer, or combinations thereof.

The buffer layer 103 can be disposed over the substrate 102. The buffer layer 103 can be disposed between the substrate 102 and the nitride-based semiconductor layer 104. The buffer layer 103 can be configured to reduce lattice and thermal mismatches between the substrate 102 and the nitride-based semiconductor layer 104, thereby curing defects due to the mismatches/difference. The buffer layer 103 may include a III-V compound. The III-V compound can include, for example but are not limited to, aluminum, gallium, indium, nitrogen, or combinations thereof. Accordingly, the exemplary materials of the buffer layer 103 can further include, for example but are not limited to, GaN, AlN, AlGaN, InAlGaN, or combinations thereof. In some embodiments, the semiconductor device 100A may further include a nucleation layer (not shown). The nucleation layer may be formed between the substrate 102 and the buffer layer 103. The nucleation layer can be configured to provide a transition to accommodate a mismatch/difference between the substrate 102 and a III-nitride layer of the buffer layer. The exemplary material of the nucleation layer can include, for example but is not limited to AlN or any of its alloys.

The nitride-based semiconductor layer 104 is disposed over the substrate 102 and the buffer layer 103. The nitride-based semiconductor layer 106 is disposed on the nitride-based semiconductor layer 104. The exemplary materials of the nitride-based semiconductor layer 104 can include, for example but are not limited to, nitrides or group III-V compounds, such as GaN, AlN, InN, InₓAl_{y}Ga_{(1-x-y)}N where x+y≤1, Al_{y}Ga_{(1-y)}N where y≤1. The exemplary materials of the nitride-based semiconductor layer 106 can include, for example but are not limited to, nitrides or group III-V compounds, such as GaN, AlN, InN, InₓAl_{y}Ga_{(1-x-y)}N where x+y≤1, Al_{y}Ga_{(1-y)}N where y≤1.

The exemplary materials of the nitride-based semiconductor layers 104 and 106 are selected such that the nitride-based semiconductor layer 106 has a bandgap (i.e., forbidden band width) greater than a bandgap of the nitride-based semiconductor layer 104, which causes electron affinities thereof different from each other and forms a heterojunction therebetween. For example, when the nitride-based semiconductor layer 104 is an undoped GaN layer having a bandgap of approximately 3.4 eV, the nitride-based semiconductor layer 106 can be selected as an AlGaN layer having bandgap of approximately 4.0 eV. As such, the nitride-based semiconductor layers 104 and 106 can serve as a channel layer and a barrier layer, respectively. A triangular well potential is generated at a bonded interface between the channel and barrier layers, so that electrons accumulate in the triangular well, thereby generating a two-dimensional electron gas (2DEG) region adjacent to the heterojunction. Accordingly, the semiconductor device 100A is available to include at least one GaN-based high-electron-mobility transistor (HEMT).

The doped nitride-based semiconductor layer 120 is disposed on/above the nitride-based semiconductor layer 106. The gate electrode 130 is disposed/stacked on the doped nitride-based semiconductor layer 120. A width of the doped nitride-based semiconductor layer 120 is substantially the same as a width of the gate electrode 130. The doped nitride-based semiconductor layer 120 is disposed between the nitride-based semiconductor layer 106 and the gate electrode 130. The doped nitride-based semiconductor layer 120 covers a portion of the nitride-based semiconductor layer 106.

In the exemplary illustration of FIG. 1A, the semiconductor device 100A is an enhancement mode device, which is in a normally-off state when the gate electrode 130 is at approximately zero bias. Specifically, the doped nitride-based semiconductor layer 120 may create at least one p-n junction with the nitride-based semiconductor layer 106 to deplete the 2DEG region, such that at least one zone of the 2DEG region corresponding to a position below the corresponding the gate electrode 130 has different characteristics (e.g., different electron concentrations) than the rest of the 2DEG region and thus is blocked. Due to such mechanism, the semiconductor device 100A has a normally-off characteristic. In other words, when no voltage is applied to the gate electrode 130 or a voltage applied to the gate electrode 130 is less than a threshold voltage (i.e., a minimum voltage required to form an inversion layer below the gate electrode 130), the zone of the 2DEG region below the gate electrode 130 is kept blocked, and thus no current flows therethrough.

In some embodiments, the doped nitride-based semiconductor layer 120 can be omitted, such that the semiconductor device 100A is a depletion-mode device, which means the semiconductor device 100A in a normally-on state at zero gate-source voltage.

The doped nitride-based semiconductor layer 120 can be a p-type doped III-V semiconductor layer. The exemplary materials of the doped nitride-based semiconductor layer 120 can include, for example but are not limited to, p-doped group III-V nitride semiconductor materials, such as p-type GaN, p-type AlGaN, p-type InN, p-type AlInN, p-type InGaN, p-type AlInGaN, or combinations thereof. In some embodiments, the p-doped materials are achieved by using a p-type impurity, such as Be, Mg, Zn, Cd, and Mg. In some embodiments, the nitride-based semiconductor layer 104 includes undoped GaN and the nitride-based semiconductor layer 106 includes AlGaN, and the doped nitride-based semiconductor layer 120 is a p-type GaN layer which can bend the underlying band structure upwards and to deplete the corresponding zone of the 2DEG region, so as to place the semiconductor device 100A into an off-state condition.

The exemplary materials of the gate electrode 130 may include metals or metal compounds. The gate electrode 130 may be formed as a single layer, or plural layers of the same or different compositions. The exemplary materials of the metals or metal compounds can include, for example but are not limited to, W, Au, Pd, Ti, Ta, Co, Ni, Pt, Mo, TiN, TaN, metal alloys or compounds thereof, or other metallic compounds.

The dielectric protection layer 140 is disposed on the nitride-based semiconductor layer 106 and the gate electrode 130. The dielectric protection layer 140 can cap/cover the gate electrode 130, the doped nitride-based semiconductor layer 120 and the nitride-based semiconductor layer 106. The dielectric protection layer 140 is in contact with the gate electrode 130, the doped nitride-based semiconductor layer 120, and the nitride-based semiconductor layer 106. The dielectric protection layer 140 is conformal with the doped nitride-based semiconductor layer 120 and the gate electrode 130. More specifically, the dielectric protection layer 140 is conformal with a profile collectively constructed by the gate electrode 130, the doped nitride-based semiconductor layer 120, and the nitride-based semiconductor layer 106 and thus can protrude from the nitride-based semiconductor layer 106.

The dielectric protection layer 140 can extend from the nitride-based semiconductor layer 106 to the gate electrode 130 through the doped nitride-based semiconductor layer 120. Specifically, form far left to far right, the dielectric protection layer 140 can extend laterally on a top surface of the nitride-based semiconductor layer 106; the dielectric protection layer 140 can extend upward along side surfaces of the doped nitride-based semiconductor layer 120 and the gate electrode 130; the dielectric protection layer 140 can extend laterally on a top surface of the gate electrode 130; the dielectric protection layer 140 can extend downward along another side surfaces of the doped nitride-based semiconductor layer 120 and the gate electrode 130; and the dielectric protection layer 140 can extend laterally on the top surface of the nitride-based semiconductor layer 106.

The material of the dielectric protection layer 140 can include, for example but are not limited to, dielectric materials. For example, the dielectric protection layer 140 can include at least one nitride-based dielectric material, such as silicon nitride (Si₃N₄). In some embodiments, the dielectric protection layer 140 includes nitride-based dielectric materials. The nitride-based dielectric materials of the dielectric protection layer 140 can include, for example but are not limited to, Hf₃N₄, AlN, BN, Si₃N₄, and combinations thereof. In some embodiments, the dielectric protection layer 140 includes oxide dielectric materials. The oxide dielectric materials of the dielectric protection layer 140 can include, for example but are not limited to, SiO₂, Ga₂O₃, Ta₂O₅, MgO, Al₂O₃, HfO₂.

The dielectric protection layer 142 is disposed on the dielectric protection layer 140 to form a dielectric multilayer structure ML. The nitride-based semiconductor layer 106 can be separated from the dielectric protection layer 142 by the dielectric protection layer 140. The dielectric protection layer 142 is in contact with the dielectric protection layer 140. The dielectric protection layer 142 can be disposed to be conformal with the dielectric protection layer 140 to form a protruding part 144 with the dielectric protection layer 140. In some embodiments, the protruding part 144 has a curved border. The curved border can redistribute stress from a layer to be formed on the dielectric protection layer 142.

The gate electrode 130 and the doped nitride-based semiconductor layer 120 are positioned directly under the protruding part 144. The protruding part 144 can span across the gate electrode 130 and the doped nitride-based semiconductor layer 120. Orthogonal projections of the gate electrode 130 and the doped nitride-based semiconductor layer 120 on the nitride-based semiconductor layer 106 are within an orthogonal projection of the protruding part 144 on the nitride-based semiconductor layer 106. The material of the dielectric protection layer 142 can be identical with or similar with that of the dielectric protection layer 140. In some embodiments, the dielectric protection layer 142 includes nitride-based dielectric materials. The nitride-based dielectric materials of the dielectric protection layer 142 can include, for example but are not limited to, Hf₃N₄, BN, Si₃N₄, and combinations thereof. In some embodiments, the dielectric protection layer 140 includes oxide dielectric materials. The oxide dielectric materials of the dielectric protection layer 142 can include, for example but are not limited to, SiO₂, Ga₂O₃, Ta₂O₅, MgO, Al₂O₃, HfO₂.

With respect to the processes for manufacturing the dielectric protection layers 140 and 142, because it is complicated to bring the processes into an ideal condition, unexpected substance might be introduced into the processes such that the unexpected substance will exist in the dielectric protection layers 140 and 142. For example, in some embodiments, the dielectric protection layers 140 and 142 may include oxygen therein. The dielectric protection layer 140 can be formed to have an oxygen concentration less than that of the dielectric protection layer 142, resulting in well protection to the doped nitride-based semiconductor layer 120 and the gate electrode 130. More details are provided as follows.

FIG. 1B is an enlarged vertical cross-sectional view of a region A in FIG. 1A according to some embodiments of the present disclosure. The dielectric protection layers 140 and 142 may be merged such that there is no distinguish interface between them. In some practical situations, the exemplary illustration of FIG. 1B can be found in scanning electron microscope (SEM). In some embodiments, to clearly show the profile of the dielectric protection layers 140 and 142 in the SEM, at least one etching process can be performed on the dielectric protection layers 140 and 142 to make the profiles thereof and the interface therebetween distinguishable. The etching process can achieve the result can refer to an etch selectivity with respect to the dielectric protection layers 140 and 142. That is, the dielectric protection layers 140 and 142 may have different etching rates with respect to the same etchant, resulting from the different compositions thereof.

For the convenience of description with respect to FIG. 1B, the relationship among the doped nitride-based semiconductor layer 120, the gate electrode 130, and the dielectric protection layers 140 and 142 are defined by specific terminologies, including:
I represents an interface between the dielectric protection layers 140 and 142;
P1 represents a position inside the dielectric protection layer 140;
P2 represents a position inside the dielectric protection layer 142;
P3 represents a position at the interface I, in which the positions
P1, P2 and P3 are located on a substantially straight line;
T1 represents a thickness of the dielectric protection layer 140;
T2 represents a thickness of the dielectric protection layer 142;
T3 represents a thickness of the doped nitride-based semiconductor layer 120; and
T4 represents a thickness of the gate electrode 130.

The dielectric protection layers 140 and 142, which are formed after the formation of the gate electrode 130 and the doped nitride-based semiconductor layer 120, can be manufactured by applying different environmental recipes, thereby resulting in different characteristics thereof. During the manufacturing stage of the dielectric protection layer 140, the dielectric protection layer 140 is formed by a deposition process having higher quality than a deposition process for forming the dielectric protection layer 142. Herein, the phrase “higher quality” may mean the process can have a high vacuum degree and a slow growth rate (i.e., a unit thickness per unit time). Accordingly, the process for forming the dielectric protection layer 140 is in a slow growth rate than the process for forming the dielectric protection layer 142. The dielectric protection layer 140 is deposited under a lower atmospheric pressure (i.e., an anoxic environment) than the dielectric protection layer 142. As such, the dielectric protection layer 140 can grow as a layer with an oxygen concentration less/lower than that of the dielectric protection layer 142. The anoxic environment would reduce the negative influence on the nitride-based semiconductor layer 106, the gate electrode 130, and the doped nitride-based semiconductor layer 120.

Considering the cost and performance, the dielectric protection layer 140 can be formed as being thin since it has a slow growth rate, and the dielectric protection layer 142 can be formed as being thick since it has a high growth rate. In this regard, for example, once a dielectric protection layer directly is formed on a nitride-based semiconductor layer, a doped nitride-based semiconductor layer, and a gate electrode by using a fast growth rate but a low vacuum degree, these layers would be damaged due to an oxic environment. Moreover, for example, once a dielectric protection layer is directly formed on a nitride-based semiconductor layer, a doped nitride-based semiconductor layer, and a gate electrode by using a slow growth rate and a low vacuum degree but having a large thickness, the cost may be high along with a long processing time.

In some embodiments, in the comparison between the dielectric protection layers 140 and 142, the dielectric protection layer 140 can have a higher compactness/density, a smaller thickness, and a lower oxygen concentration; and the dielectric protection layer 142 can have a lower compactness/density, a larger thickness, and a higher oxygen concentration.

In some embodiments, between the formation of the dielectric protection layer 140 and the formation of the dielectric protection layer 142, a breaking vacuum stage is performed. Therefore, prior to the formation of the dielectric protection layer 142, oxygen may be distributed at the top surface of the dielectric protection layer 140. After the formation of the dielectric protection layer 142, the two dielectric protection layers form an interface I therebetween at which oxygen is distributed. After the formation of the dielectric protection layer 140, even if it is required to move the device, the dielectric protection layer 140 can protect the device from external pollutants, which is achieved by the high compactness/density of the dielectric protection layer 140.

FIG. 1C is an oxygen concentration distribution in the semiconductor device 100A. Referring to FIGS. 1B and 1C, as afore-mentioned, both of the dielectric protection layers 140 and 142 can include oxygen. The oxygen concentration of the dielectric protection layer 142 (i.e., the position P2) is greater than that of the dielectric protection layer 140 (i.e., the position P1). The oxygen concentration at the interface I (i.e., the position P3) is greater than those of the dielectric protection layers 140 and 142 (i.e., the positions Pb and P2). The peak of oxygen concentration of the multilayer structure ML occurs at the interface I between the dielectric protection layers 140 and 142. That is, the multilayer structure ML has an oxygen concentration increasing and then decreasing from the dielectric protection layer 142 to the dielectric protection layer 140 through the interface I.

The dielectric protection layer 142 is thicker than the dielectric protection layer 140 (i.e., T2>T1). In some embodiments, a ratio of a thickness of the dielectric protection layer 140 to a thickness of the dielectric protection layer 142 is in a range from 0.01 to 0.5, which will be advantageous to improvement of the performance with considering the cost (e.g., consideration of the growth time of the dielectric protection layer 140). Since the dielectric protection layer 142 is disposed on and thicker than the dielectric protection layer 140, the dielectric protection layer 142 can block the outside moisture or impurities. On the other hand, the sum of thickness of the doped nitride-based semiconductor layer 120 and the gate electrode 130 (i.e., T3+T4) is greater than the sum of thickness of the dielectric protection layers 140 and 142 (i.e., T1+T2). Such a configuration is to prevent the semiconductor device 100 from becoming too thick.

Briefly, by the dielectric protection layer 140, the probability of oxidizing the element layers beneath the dielectric protection layer 140 can be reduced, so as to avoid the negative influence of oxidation on the electrical properties of these element layers. Additionally, the dielectric protection layer 140 can protect these element layers from damage or contamination in the subsequent processes. Moreover, the dielectric protection layer 140 can prevent the oxygen from diffusing into these element layers owing to its good compactness/density, which means that the dielectric protection layer 140 can serve as an oxygen blocking layer.

FIG. 1D, FIG. 1E and FIG. 1F show different oxygen concentration distributions in the semiconductor device 100A according to some embodiments of the present disclosure. The multilayer structure ML can have different oxygen concentration distributions from the oxygen concentration distribution in the FIG. 1C. In some embodiments, as shown in FIG. 1D, the oxygen concentration at the position P2 is substantially the same as the oxygen concentration at the position P3, and is greater than the oxygen concentration at the position P1. In some embodiments, as shown in FIG. 1E, the oxygen concentration at the positions P1 and P2 is less than the oxygen concentration at the position P3, and the oxygen concentration at the position P1 is greater than the oxygen concentration at the position P2. In some embodiments, as shown in FIG. 1F, the oxygen concentration at the position P1 is substantially the same as the oxygen concentration at the position P3, and is greater than the oxygen concentration at the position P2. These different oxygen concentrations in the multilayer structure ML can be achieved by controlling the oxygen concentration during the manufacturing stages so as to comply with different electrical requirements.

In addition, the dielectric protection layer 142 can be doped with chlorine due to introducing SiH₂CL₂ gas during the manufacturing stage of the dielectric protection layer 142. The dielectric protection layer 140 can be devoid of chlorine since the manufacturing stage of the dielectric protection layer 140 is performed without introducing SiH₂CL₂ gas. As such, the dielectric protection layer 142 has a chlorine concentration greater than that of the dielectric protection layer 140. This difference can result from the different processes for the dielectric protection layers 140 and 142. For example, the fast growth rate of the dielectric protection layer 142 may be require the SiH₂CL₂ gas.

Referring to FIG. 1A again, the S/D electrodes 110 and 112 are disposed on the nitride-based semiconductor layer 106. The S/D electrodes 110 and 112 can penetrate the dielectric protection layers 140 and 142 to make contact with the nitride-based semiconductor layer 106. The “S/D” electrode means each of the S/D electrodes 110 and 112 can serve as a source electrode or a drain electrode, depending on the device design. In some embodiments, the S/D electrodes 110 and 112 can include, for example but are not limited to, metals, alloys, doped semiconductor materials (such as doped crystalline silicon), compounds such as silicides and nitrides, other conductor materials, or combinations thereof. The exemplary materials of the S/D electrodes 110 and 112 can include, for example but are not limited to, Ti, AlSi, TiN, or combinations thereof. The S/D electrodes 110 and 112 may be a single layer, or plural layers of the same or different composition. In some embodiments, the S/D electrodes 110 and 112 form ohmic contacts with the nitride-based semiconductor layer 106. The ohmic contacts can be achieved by applying Ti, Al, or other suitable materials to the S/D electrodes 110 and 112. In some embodiments, each of the S/D electrodes 110 and 112 is formed by at least one conformal layer and a conductive filling. The conformal layer can wrap the conductive filling. The exemplary materials of the conformal layer, for example but are not limited to, Ti, Ta, TiN, Al, Au, AlSi, Ni, Pt, or combinations thereof. The exemplary materials of the conductive filling can include, for example but are not limited to, AlSi, AlCu, or combinations thereof.

The doped nitride-based semiconductor layer 120 and the gate electrode 130 are located between the S/D electrodes 110 and 112. That is, the S/D electrodes 110 and 112 can be located at two opposite sides of the gate electrode 130, respectively. In some embodiments, other configurations may be used, particularly when plural source, drain, or gate electrodes are employed in the device. In the exemplary illustration of FIG. 1A, the S/D electrodes 110 and 112 are symmetrical about the gate electrode 130. In other embodiments, the S/D electrodes 110 and 112 are asymmetrical about the gate electrode 130. For example, the S/D electrode 110 can be closer to the gate electrode 130 than the S/D electrode 112.

The passivation layer 150 covers the dielectric protection layer 142 and the S/D electrodes 110 and 112. The passivation layer 150 can be formed for a protection purpose or for enhancing the electrical properties of the device (e.g., by providing an electrical isolation effect between/among different layers/elements). The passivation layer 150 can serve as a planarization layer which has a level top surface to support other layers/elements. In some embodiments, the passivation layer 150 can be formed as a thicker layer, and a planarization process, such as chemical mechanical polish (CMP) process, is performed on the passivation layer 150 to remove the excess portions, thereby forming a level top surface. The exemplary materials of the passivation layer 150 can include, for example but are not limited to, SiNₓ, SiOₓ, Si₃N₄, SiON, SiC, SiBN, SiCBN, oxides, nitrides, poly(2-ethyl-2-oxazoline) (PEOX), or combinations thereof. In some embodiments, the passivation layer 150 can be a multi-layered structure, such as a composite dielectric layer of Al₂O₃/SiN, Al₂O₃/SiO₂, AlN/SiN, AlN/SiO₂, or combinations thereof.

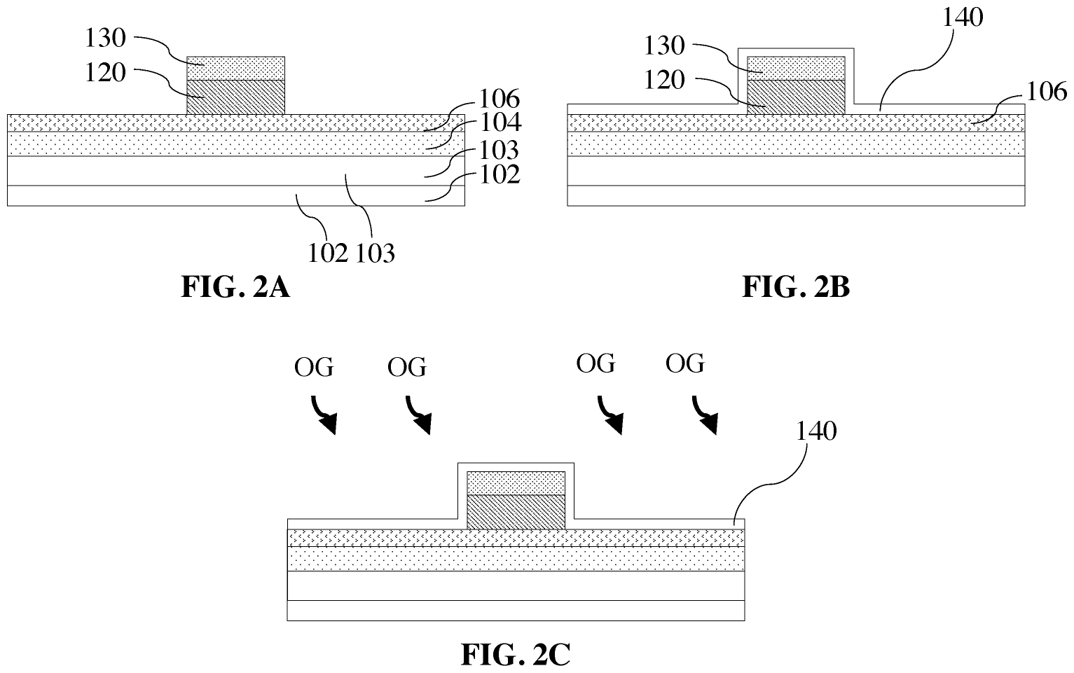

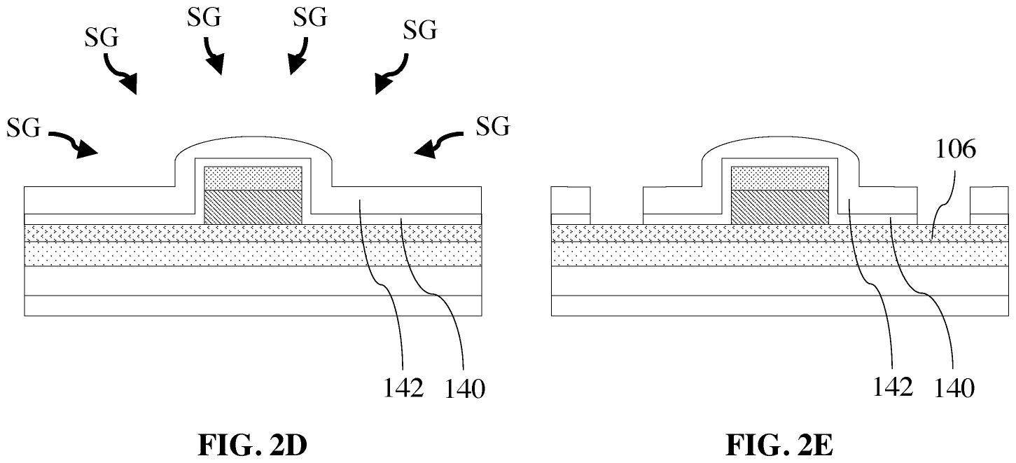

Different stages of a method for manufacturing the semiconductor device 100A are shown in FIG. 2A, FIG. 2B, FIG. 2C, FIG. 2D and FIG. 2E, described below. In the following, deposition techniques can include, for example but are not limited to, atomic layer deposition (ALD), physical vapor deposition (PVD), chemical vapor deposition (CVD), metal organic CVD (MOCVD), plasma enhanced CVD (PECVD), low-pressure CVD (LPCVD), plasma-assisted vapor deposition, epitaxial growth, or other suitable processes.

Referring to FIG. 2A, a substrate 102 is provided. A buffer layer 103, nitride-based semiconductor layers 104, 106 can be formed over the substrate 102 in sequence by using deposition techniques. To be more specific, the buffer layer 103 is formed on a substrate 102. The nitride-based semiconductor layer 104 is formed on the buffer layer 103. The nitride-based semiconductor layer 106 is formed on the nitride-based semiconductor layer 104. Thereafter, a doped nitride-based semiconductor layer 120 and a gate electrode 130 can be formed over the nitride-based semiconductor layer 106. The formation of the doped nitride-based semiconductor layer 120 and the gate electrode 130 includes deposition techniques and a patterning process. In some embodiments, the deposition techniques can be performed for forming a blanket layer, and the patterning process can be performed for removing excess portions thereof. In some embodiments, the patterning process can include photolithography, exposure and development, etching, other suitable processes, or combinations thereof.

Referring to FIG. 2B, a dielectric protection layer 140 can be formed/deposited over the doped nitride-based semiconductor layer 120, the gate electrode 130, and the nitride-based semiconductor layer 106. The formation of the dielectric protection layer 140 is performed using an environment of a high vacuum degree. In some embodiments, the formation of the dielectric protection layer 140 is without introducing SiH₂CL₂ gas. The dielectric protection layer 140 can grow at a slow growth rate (i.e., the thickness per time), so as to achieve a good compactness/density. As such, the dielectric protection layer 140 with a high compactness/density, a low thickness, and a low oxygen concentration is formed.

Referring to FIG. 2C, a breaking vacuum stage is performed such that the oxygen OG can distribute on a top surface of the dielectric protection layer 140.

Referring to FIG. 2D, a dielectric protection layer 142 can be formed/deposited over the dielectric protection layer 140. The formation of the dielectric protection layer 142 is performed using an environment of a low high vacuum degree than the stage of FIG. 2B. The formation of the dielectric protection layer 142 is by introducing SiH₂CL₂ gas SG in a chamber/furnace. The dielectric protection layer 142 can grow at a faster growth rate (i.e., the thickness per time) than that of the dielectric protection layer 140.

As such, the dielectric protection layer 140 is formed to have an oxygen concentration less than that of the dielectric protection layer 142 and is thinner than the dielectric protection layer 142. After the formation of the dielectric protection layer 142, an interface is correspondingly formed between the dielectric protection layers 140 and 142, which contains oxygen atoms due to breaking vacuum.

Referring to FIG. 2E, contact openings are formed in the dielectric protection layers 140 and 142 by removing some portions of the dielectric protection layers 140 and 142, so as to expose a part of the nitride-based semiconductor layer 106. Thereafter, S/D electrodes 110 and 112 and a passivation layer 150 can be formed, obtaining the configuration of the semiconductor device 100A as shown in FIG. 1A.

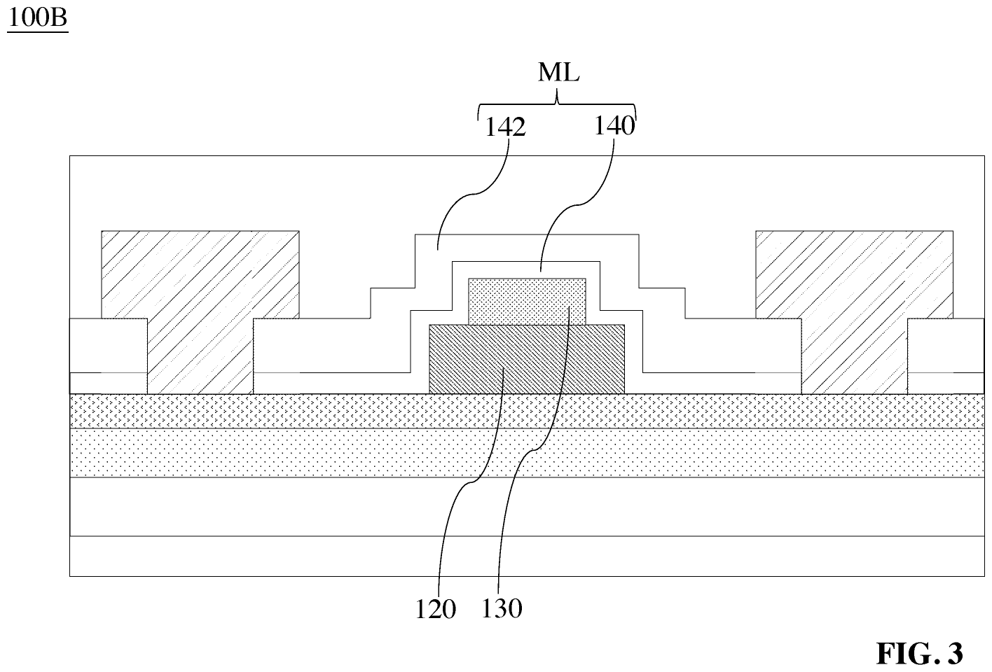

FIG. 3 is a cross-sectional view of a semiconductor device 100B according to some embodiments of the present disclosure. In the exemplary illustration of FIG. 3, a width of the gate electrode 130 is less than a width of the doped nitride-based semiconductor layer 120 so as to constitute a stepwise profile. The dielectric protection layer 140 can have a stepwise profile since it is deposited on a combination structure of the doped nitride-based semiconductor layer 120 and the gate electrode 130. The dielectric protection layer 142 is conformally disposed with the dielectric protection layer 140, thereby having a stepwise profile as well. The method for manufacturing the semiconductor device 100B can be similar to the manufacturing method of the semiconductor device 100A. The profile of the combination structure of the doped nitride-based semiconductor layer 120 and the gate electrode 130 can be achieved by controlling the pattern of the photomasks using in the manufacturing stages thereof.

It should be noted that the above semiconductor devices can be manufactured by the afore-mentioned different processes in order to meet different electrical requirements.

Based on the above descriptions, in the present disclosure, the semiconductor device is provided with a multilayer structure including at least two dielectric protection layers. The dielectric protection layer in contact with the gate electrode and the doped nitride-based semiconductor layer has a lower oxygen concentration and is thinner than another one dielectric protection layer, such that a good protection to the gate electrode and the doped nitride-based semiconductor layer is achieved. Accordingly, the semiconductor device of the present disclosure can have good electrical properties and reliability.

The embodiments were chosen and described in order to best explain the principles of the disclosure and its practical application, thereby enabling others skilled in the art to understand the disclosure for various embodiments and with various modifications that are suited to the particular use contemplated.

As used herein and not otherwise defined, the terms “substantially,” “substantial,” “approximately” and “about” are used to describe and account for small variations. When used in conjunction with an event or circumstance, the terms can encompass instances in which the event or circumstance occurs precisely as well as instances in which the event or circumstance occurs to a close approximation. For example, when used in conjunction with a numerical value, the terms can encompass a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. The term “substantially coplanar” can refer to two surfaces within micrometers of lying along a same plane, such as within 40 μm, within 30 μm, within 20 μm, within 10 μm, or within 1 μm of lying along the same plane.

As used herein, the singular terms “a,” “an,” and “the” may include plural referents unless the context clearly dictates otherwise. In the description of some embodiments, a component provided “on” or “over” another component can encompass cases where the former component is directly on (e.g., in physical contact with) the latter component, as well as cases where one or more intervening components are located between the former component and the latter component.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not necessarily be drawn to scale. There may be distinctions between the artistic renditions in the present disclosure and the actual apparatus due to manufacturing processes and tolerances. Further, it is understood that actual devices and layers may deviate from the rectangular layer depictions of the FIGS. and may include angles surfaces or edges, rounded corners, etc. due to manufacturing processes such as conformal deposition, etching, etc. There may be other embodiments of the present disclosure which are not specifically illustrated. The specification and the drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations.

1. A semiconductor device comprising:
a substrate;
a first nitride-based semiconductor layer disposed above the substrate;
a second nitride-based semiconductor layer disposed on the first nitride-based semiconductor layer and having a bandgap greater than a bandgap of the first nitride-based semiconductor layer;
a doped nitride-based semiconductor layer disposed over the second nitride-based semiconductor layer;
a gate electrode disposed on the doped nitride-based semiconductor layer;
a first dielectric protection layer including oxygen and disposed on the gate electrode and the second nitride-based semiconductor layer, wherein the first dielectric protection layer is conformal with a profile collectively constructed by the gate electrode, the doped nitride-based semiconductor layer, and the second nitride-based semiconductor layer; and
a second dielectric protection layer including oxygen and disposed on and in contact with the first dielectric protection layer, wherein the first dielectric protection layer has an oxygen concentration less than that of the second dielectric protection layer.

2. The semiconductor device of claim 1, wherein the second dielectric protection layer is conformal with the first dielectric protection layer and is thicker than the first dielectric protection layer.

3. The semiconductor device of claim 2, wherein the sum of thickness of the doped nitride-based semiconductor layer and the gate electrode is greater than the sum of thickness of the first and second dielectric protection layers.

4. The semiconductor device of claim 1, wherein a ratio of a thickness of the first dielectric protection layer to a thickness of the second dielectric protection layer is in a range from 0.01 to 0.5.

5. The semiconductor device of claim 1, wherein the first and second dielectric protection layers forms an interface therebetween at which oxygen is distributed.

6. The semiconductor device of claim wherein an oxygen concentration at the interface is greater than the oxygen concentration of the second dielectric protection layer.

7. The semiconductor device of claim 1, wherein the second dielectric protection layer has a chlorine concentration greater than that of the first dielectric protection layer.

8. The semiconductor device of claim 1, wherein the second dielectric protection layer is doped with chlorine.

9. The semiconductor device of claim 8, wherein the first dielectric protection layer is devoid of chlorine.

10. The semiconductor device of claim 1, wherein the first dielectric protection layer extends from the second nitride-based semiconductor layer to the doped nitride-based semiconductor layer.

11. The semiconductor device of claim 10, wherein the first dielectric protection layer extends from the doped nitride-based semiconductor layer to the gate electrode.

12. The semiconductor device of claim 11, wherein the first dielectric protection layer extends laterally on a top surface of the gate electrode.

13. The semiconductor device of claim 1, further comprising a source/drain (S/D) electrode penetrating the first and second dielectric protection layers to make contact with the second nitride-based semiconductor layer.

14. The semiconductor device of claim 1, wherein both of the first and second dielectric protection layers comprises silicon nitride (Si₃N₄).

15. The semiconductor device of claim 1, wherein the second nitride-based semiconductor layer is separated from the second dielectric protection layer by the first dielectric protection layer.

16. A manufacturing method of a semiconductor device, comprising:
forming a first nitride-based semiconductor layer;
forming a second nitride-based semiconductor layer on the first nitride-based semiconductor layer;
forming a doped nitride-based semiconductor layer over the second nitride-based semiconductor layer;
forming a gate electrode on the doped nitride-based semiconductor layer;
forming a first dielectric protection layer including oxygen and on the gate electrode and the second nitride-based semiconductor layer; and
forming a second dielectric protection layer including oxygen and on and in contact with the first dielectric protection layer, wherein the first dielectric protection layer has an oxygen concentration less than that of the second dielectric protection layer and is thinner than the second dielectric protection layer.

17. The manufacturing method of claim 16, further comprising:
breaking vacuum after forming the first dielectric protection layer and prior to forming the second dielectric protection layer.

18. The manufacturing method of claim 17, wherein an interface formed between the first and second dielectric protection layers contains oxygen due to breaking vacuum.

19. The manufacturing method of claim 16, wherein forming the second dielectric protection layer is performed with introducing SiH₂CL₂ gas.

20. The manufacturing method of claim 18, wherein forming the first dielectric protection layer is performed without introducing SiH₂CL₂ gas.

21-25. (canceled)
